(19) United States
(12) Patent Application Publication
(10) Pub. No.: US 2023/0373018 A1
(43) Pub. Date: Nov. 23, 2023

(54) DUAL BLADE CONFIGURATION FOR WAFER EDGE TRIMMING PROCESS

(71) Applicant: Taiwan Semiconductor Manufacturing Company, Ltd., Hsinchu (TW)

(72) Inventors: Ming-Che Lee, Tainan City (TW); Kuo-Ming Wu, Zhubei City (TW); Sheng-Chau Chen, Tainan City (TW); Ping-Tzu Chen, Tainan City (TW)

(21) Appl. No.: 17/750,951

(22) Filed: May 23, 2022

(51) Int. Cl. B23C 3/12; H01L 23/00; H01L 21/304; B23C 3/34

(52) U.S. Cl. CPC B23C 3/12; H01L 24/83; H01L 21/3043; B23C 3/34; H01L 2224/83947; H01L 2924/35121; H01L 24/32; H01L 2224/32145

(57) ABSTRACT

In some embodiments, the present disclosure relates to a method that includes bonding a first wafer to a second wafer to form a wafer stack and removing a top portion of the second wafer. A first trim blade having a first blade width is aligned over the second wafer. The first trim blade is used to form a trench that separates a central portion of the second wafer from a peripheral portion of the second wafer. The trench is arranged at a first distance from an outer perimeter of the second wafer, and extends from a top surface of the second wafer to a trench depth beneath the top surface of the first wafer. A second trim blade having a second blade width is aligned over the peripheral portion, the second blade width being greater than the first blade width. The peripheral portion is removed using the second trim blade.

### BACKGROUND

Semiconductor device fabrication is a process used to create integrated circuits that are present in everyday electronic devices. The fabrication process is a multiple-step sequence of photolithographic and chemical processing steps during which electronic circuits are gradually created on a wafer composed of a semiconductor material. After fabricating integrated circuits on a first wafer, the first wafer may be bonded to a second wafer. Wafer edge trimming may be used to remove and/or prevent damage to the first and second wafers after bonding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate perspective views of a method of removing a peripheral portion of a second wafer, wherein the second wafer is bonded to a first wafer, using a dual trim blade tool to mitigate peeling of the bonding layers.

FIG. 2 illustrates a flow diagram of some embodiments of a method of removing a peripheral portion of a second wafer, wherein the second wafer is bonded to a first wafer, using a dual trim blade tool to mitigate peeling of the bonding layers.

FIGS. 3, 4, 5A, 5B, 6, 7, 8, 9A, and 9B illustrate cross-sectional views of some embodiments of a method of removing a peripheral portion of a second wafer, wherein the second wafer is bonded to a first wafer, using a dual trim blade tool to mitigate peeling of the bonding layers.

FIG. 10 illustrates a cross-sectional view of some embodiments of a dual blade trimming tool comprising a position sensor, a first trim blade configured to form an annular trench in the second wafer, and a second trim blade configured to remove a peripheral portion of a second wafer.

FIGS. 11A-11C illustrate various views of some embodiments of a second wafer arranged over and bonded to a first wafer, wherein a step structure extends from the first wafer.

FIGS. 12A-12B illustrate cross-sectional views of some embodiments of a second wafer arranged over and bonded to a first wafer, wherein a step structure extends from the first wafer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

After fabricating integrated circuits on a first wafer, the first wafer may be bonded to a second wafer. However, some portion of the second wafer (e.g., an outer edge of the second wafer) may remain unbonded to the first wafer, and these unbonded portions of the second wafer may be removed by a wafer edge trimming process to mitigate or prevent peeling at the edges of the first and second wafers. Without the wafer edge trimming process, peeling of the second wafer away from the first wafer may begin around the unbonded portions during further processing steps such as, for example, packaging and dicing of the first and second wafers. To perform the wafer edge trimming process, a blade is utilized to remove peripheral portions containing the unbonded portions of the second wafer. However, the abrasiveness of the blade may cause greater peeling to occur along the edges of the second wafer. One alternative to reduce the peeling caused by this process would be to extend an inner edge of the blade into a central portion of the second wafer past the unbonded portions; however, this approach would leave less of the second wafer remaining for further processing, thereby lowering the output and efficiency of the method.

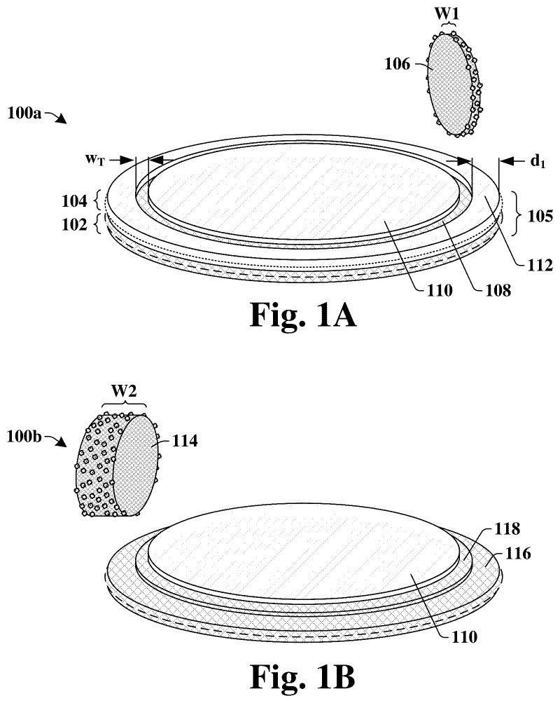

FIGS. 1A-1B illustrate perspective views 100a-100b of a method in accordance with some aspects of this disclosure. FIG. 1A shows that after a first wafer 102 is bonded to a second wafer 104 to form a wafer stack 105, a first trimming process is conducted using a first trim blade 106. The first trim blade 106 has a first blade width W1 and may be used to form an annular trench 108 within the second wafer 104. The annular trench has a trench width, Wt, and Wt is substantially equal to W1. In some embodiments, the annular trench 108 is a continuously connected circle concentric within the second wafer. The annular trench 108 is spaced a first distance dl away from the circumferential edge of the second wafer 104, wherein the first distance dl is greater than the trench width Wt. The annular trench 108 advantageously separates a central portion 110 and a peripheral portion 112 of the second wafer 104 and extends from the top of the second wafer 104 to beyond bonding layers bonding the first wafer 102 and the second wafer 104.

FIG. 1B shows that, after the formation of the annular trench 108, a second trimming process is conducted using a second trim blade 114 with a second blade width W2 that is greater than the first blade width W1. The second trimming process defines a base portion 116 and a step structure 118 of the first wafer 102.

In going from FIG. 1A to FIG. 1B, forces from the second trim blade 114 used to remove the peripheral portion 112 do not affect the central portion 110 due to the annular trench 108 separating the central portion 110 from the peripheral portion 112, leading to a mitigation or elimination of peeling around the outer edge of the central portion 110 of the second wafer 104. The second trim blade 114 removes the peripheral portion 112 of the second wafer 104 defined by the annular trench 108 to prepare the wafer stack for further processing. By using a dual trim blade method over other techniques (e.g., a single second trim blade), an inner sidewall of the annular trench 108 facing an unbonded portion of the first and second wafers 104, 102 is less than 500 micrometers from the unbonded portion, reducing the amount of the bonded portion that is removed. Peeling between the first and second wafers 104, 102 is mitigated or eliminated. This provides more usable footprint on the wafer.

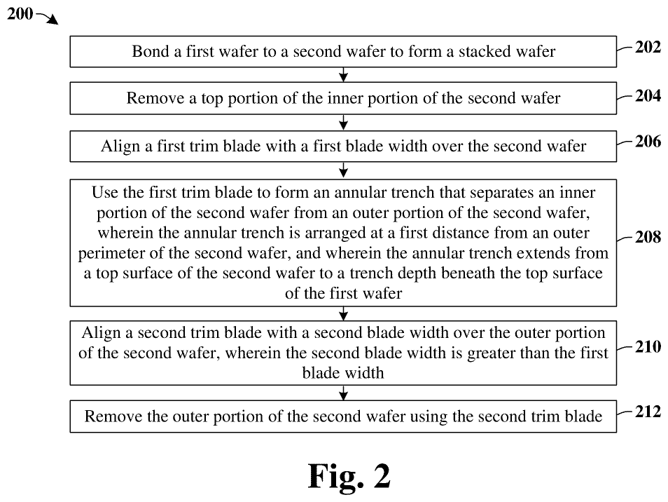

FIG. 2 illustrates a flow diagram of some embodiments of a method 200 of removing a peripheral portion of a second wafer, wherein the second wafer is bonded to a first wafer, using a dual trim blade tool to mitigate peeling of the bonding layers.

While method 200 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 202, a first wafer is bonded to a second wafer to form a wafer stack. At act 204, a top portion of the second wafer is removed. At act 206, a first trim blade with a first blade width T1 is aligned over the second wafer. At act 208, the first trim blade is used to form an annular trench that separates a central portion of the second wafer from a peripheral portion of the second wafer, wherein the annular trench is arranged at a first distance from an outer perimeter of the second wafer, and wherein the annular trench extends from a top surface of the second wafer to an annular trench depth beneath the top surface of the first wafer. At act 210, a second trim blade with a second blade width T2 is aligned over the peripheral portion of the second wafer, wherein the second blade width T2 is greater than the first blade width T1. At act 212, the peripheral portion of the second wafer is removed using the second trim blade.

By forming the annular trench separating the central portion and the peripheral portion of the second wafer, the method can eliminate contact between the bonded surface of the central portion and the second trim blade removing the peripheral portion, thereby eliminating any peeling caused by the second trim blade. By having the annular trench formed using the first trim blade within the bonded portion of the wafer stack, the method can eliminate peeling that begins in the unbonded area and reduce the amount of the bonded area that is removed in the edge trimming process. Such an approach may be useful to increase the useable output of the wafer stack and increase the number of bonded dies available in later processes.

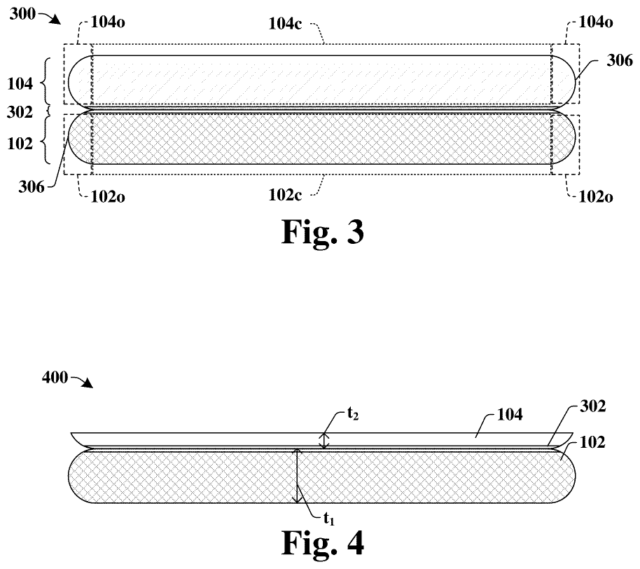

FIGS. 3, 4, 5A, 5B, 6, 7, 8, 9A, and 9B illustrate cross-sectional views 300, 400, 500a, 500b, 600, 700, 800, 900a, 900b, of some embodiments of a method of removing a peripheral portion of a second wafer, wherein the second wafer is bonded to a first wafer, using a dual trim blade tool to mitigate peeling of the bonding layers.

FIG. 3 illustrates a first wafer 102 bonded to a second wafer 104 through bonding layers 302, and thus may be consistent with some examples of act 202 in FIG. 2. In some embodiments, the first and/or second wafers 102, 104 may each be or comprise any type of semiconductor wafer (e.g., silicon/CMOS bulk, SiGe, SOI, etc.). In some embodiments, the first and/or second wafers 102, 104 may also have semiconductor devices and/or metal routing arranged on or within the first and/or second wafers 102, 104. For example, in some embodiments, semiconductor devices may be arranged on or within the first wafer 102, and semiconductor devices may be arranged on or within the second wafer 104. In some embodiments, metal routing connections may be arranged within the bonding layers 302 of the first wafer 102 and the second wafer 104. Thus, in such embodiments, the metal routing connections arranged within the first wafer 102 and the second wafer 104 may connect to one another during the bonding of the first and second wafers 102, 104 such that semiconductor devices on the first wafer 102 are coupled to semiconductor devices on the second wafer 104. Examples of the first and second metal routing connections include solder bumps, wires, or the like.

The first wafer 102 and second wafer 104 each include an outer circumferential edge 306. The first wafer 102 and second wafer 104 each have central portions that have planar faces, and outermost edges that are curved or rounded. Thus, a first central portion 102c of the first wafer 102 has a planar surface that is bonded to a corresponding planar surface of a second, central portion 104c of the second wafer 104. At the outer edges of the first wafer 102 and second wafer 104, a first outermost edge 102o of the first wafer has a first curved surface that curves away from a second curved surface of a second outermost edge 104o of the second wafer.

In some embodiments, a first bonding layer of the bonding layers 302 may be formed on the first wafer 102 through a thermal oxidation or a deposition process (e.g., physical vapor deposition (PVD), chemical vapor deposition (CVD), atomic layer deposition (ALD), etc.). In some embodiments, the bonding layers 302 may comprise, for example, an oxide (e.g., silicon dioxide, silicon oxynitride) or some other suitable dielectric material. Then, in some embodiments, the second wafer 104 may be bonded to the first wafer 102 through the bonding layers 302 by way of pressure and/or temperature changes, for example. In some embodiments, the bonding layer 114 has a thickness in a range of between, for example, approximately 1 nanometer and approximately 30 micrometers.

FIG. 4 illustrates the second wafer 104 having a top portion removed. In some embodiments, the top portion is removed using a planarization (e.g., a chemical mechanical planarization (CMP)) process. Other removal processes have been contemplated and are within the scope of this disclosure. After the top portion is removed, the first wafer 102 has a first thickness t₁ and the second wafer 104 has a second thickness t₂ that is less than the first thickness t₁. In some embodiments, the second thickness t₂ is approximately between 50 micrometers and 200 micrometers, between 50 micrometers and 100 micrometers, between 100 micrometers and 300 micrometers, or approximately within another suitable range. FIG. 4 illustrates a cross-sectional view 400 of some embodiments corresponding to act 204 of FIG. 2.

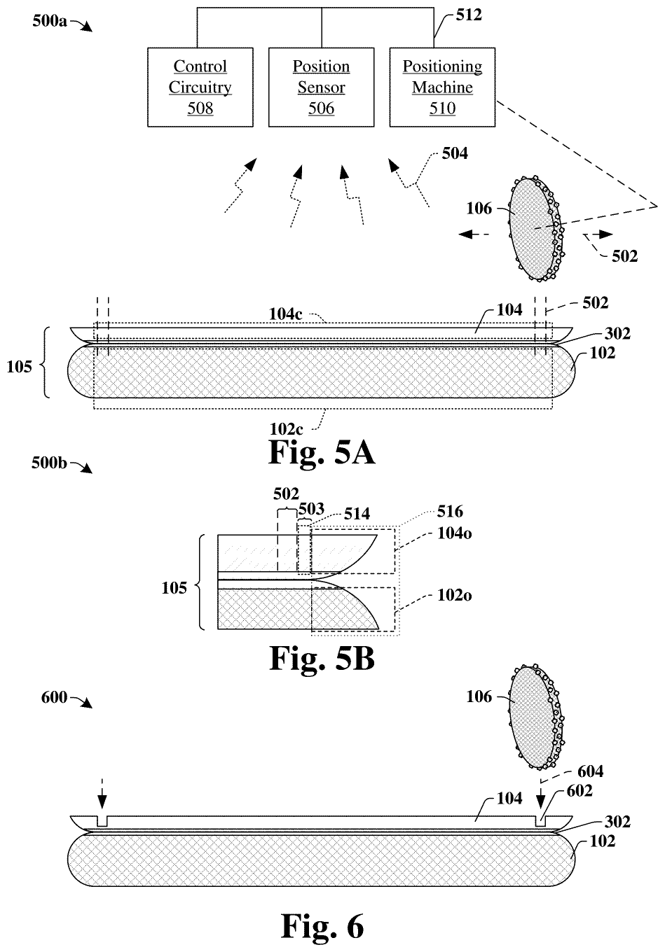

FIG. 5A illustrates a first trim blade 106 being aligned with the second wafer 104, and can be consistent with some embodiments corresponding to act 206 of FIG. 2. The alignment 502 of the first trim blade 106 is performed based on sensor data 504 (e.g., position data, alignment data, etc.) of the wafer stack 105 that is read by a position sensor 506. The position sensor 506 passes the sensor data 504 to the control circuitry 508, which then delivers instructions to a positioning machine 510 which controls the alignment 502 of the first trim blade 106.

FIG. 5B illustrates the alignment 502 of the first trim blade in relation to a bonded portion 514 and an unbonded portion 516 of the peripheral portion 112. In some embodiments, the first trim blade 106 is aligned with the second wafer 104 such that the first trim blade has an outer blade edge that resides directly over the central portion 104c where the first and second wafers are bonded to one another, and such that the first trim blade is spaced apart from the outermost, curved edges of the wafers by a distance 503. In some embodiments, the distance 503 between the outer edge of the first trim blade 106 (see FIG. 5A) and the unbonded portion 516 of the wafer stack 105 is between 0 and 100 micrometers. In further embodiments, the bonded portion 514 between the outer edge of the first trim blade 106 and the unbonded portion 516 has a first width which is between 0 and 100 micrometers, while the unbonded portion 516 comprises both the first outermost edge 102o and the second outermost edge 104o and has a second width that is greater than the first width.

FIG. 6 illustrates the first trim blade 106 forming a partial annular trench 602 within the second wafer 104. The partial annular trench 602 is circular, concentric with the second wafer 104, and is formed due to a first cut 604 being made using the first trim blade 106. The partial annular trench 602 is formed in the bonded portion of the first wafer, which helps to reduce cracking and/or peeling in the wafer stack 105. The partial annular trench 602 has a partial annular trench depth approximately between 30 micrometers and 100 micrometers, between 30 micrometers and 60 micrometers, between 60 micrometers and 100 micrometers, or approximately within another suitable range. The partial annular trench 602 has a bottommost surface that is above a topmost surface of the bonding layers 302. In some embodiments, the total distance between the unbonded portion 516 (see FIG. 5B) of the wafer stack 105 and the inner sidewall of the partial annular trench is less than 500 micrometers. In some embodiments, the partial annular trench is arranged at a first distance from an outer perimeter of the second wafer 104. In some embodiments, the first distance is between 1.5 millimeters and 2.5 millimeters, between 1 and 2 millimeters, between 2 and 3 millimeters, or approximately within another suitable range.

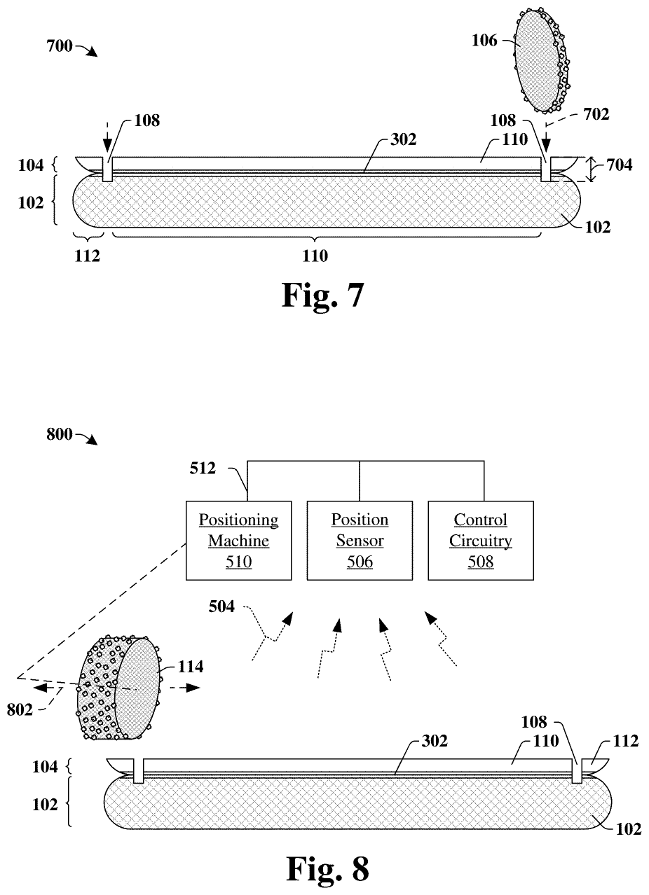

FIG. 7 illustrates the end of the first trimming process where the first trim blade 106 deepens the partial annual trench to form an annular trench 108 within the second wafer 104 and the first wafer 102. The annular trench 108 is formed due to a second cut 702 being made using the first trim blade 106 within the partial annular trench 602 (see FIG. 6). The second cut 702 follows the path of the first cut 604 (see FIG. 6). In some embodiments, the first trim blade 106 is re-aligned with the wafer stack 105 before the second cut 702 is made. In other embodiments, the first trim blade 106 is already aligned with the partial annular trench 602 (see FIG. 6) and is not re-aligned before the second cut 702 is made. In some embodiments, the alignment of the first trim blade 106 is verified using position sensors (not shown) before the second cut 702 is made. In some embodiments, the annular trench has a first annular width corresponding to the first blade width W1 of the first trim blade 106 and the peripheral portion 112 has a second annular width that is less than the second blade width W2 of the second trim blade 114. The annular trench 108 is formed in the central portions where the first and second wafers are bonded to one another at a planar surface, thereby helping to reduce cracking and/or peeling in the wafer stack 105. In some embodiments, the first annular width is approximately between 100 micrometers and 200 micrometers, between 50 micrometers and 150 micrometers, between 150 micrometers and 300 micrometers, or approximately within another suitable range. The annular trench 108 extends through the bonding layers 302 and into the first wafer 102 to an annular trench depth 704. In some embodiments, the annular trench depth 704 is approximately between 70 micrometers and 170 micrometers, between 60 micrometers and 120 micrometers, between 120 micrometers and 220 micrometers, or approximately within another suitable range. In some embodiments, the unbonded portion 516 (see FIG. 5B) of the peripheral portion 112 is spaced from the central portion 110 by both the bonded portion 514 (see FIG. 5B) and the annular trench 108. FIGS. 6-7 illustrate cross-sectional views 600-700 of some embodiments corresponding to act 208 of FIG. 2.

FIG. 8 illustrates a second trim blade 114 being aligned with the second wafer 104, and can be consistent with some embodiments corresponding to act 210 of FIG. 2. The alignment 802 of the first trim blade 106 is performed based on sensor data 504 of the wafer stack 105 that is read by a position sensor 506. The position sensor 506 passes the sensor data 504 to the control circuitry 508, which then delivers instructions to a positioning machine 510 which controls the alignment 802 of the second trim blade 114. In some embodiments, the second trim blade 114 is aligned with the second wafer 104 such that the inner edge of the second trim blade 114 is aligned with the outer sidewall of the annular trench 108. In other embodiments, the inner edge of the second trim blade 114 is substantially centered between sidewalls of the annular trench 108.

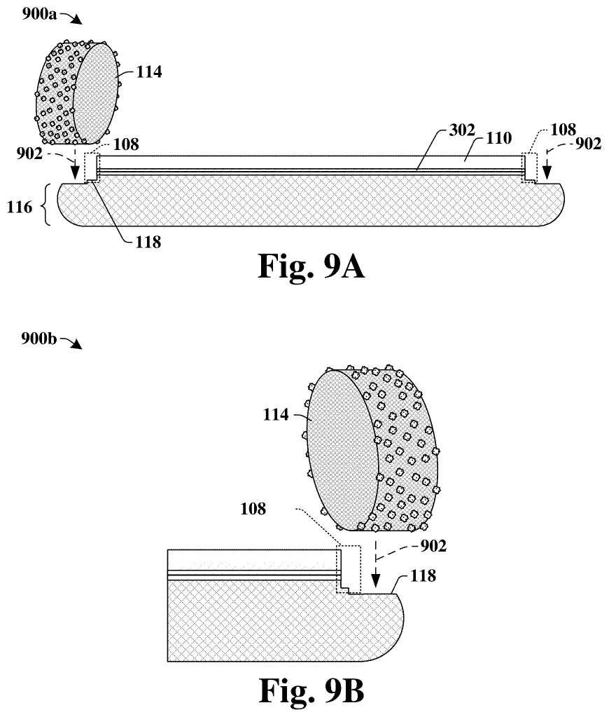

FIGS. 9A-9B illustrate a second trimming process where the second trim blade 114 is aligned with the second wafer and removes the peripheral portion 112 of the second wafer 104. In some embodiments, the peripheral portion of the annular trench is removed due to a third cut 902 being made using the second trim blade 114. The process of removing the peripheral portion 112 of the second wafer 104 exposes a step structure 118 of the first wafer 102 and a base portion 116 of the first wafer 102. The step structure 118 separates the base portion 116 from the bonding layers 302 and is delineated by the bottom of the annular trench 108 (shown in phantom) and an outer sidewall formed by the second trim blade 114. The base portion 116 extends beneath the step structure 118 and has an uppermost surface 116u exposed by the third cut 902. In some embodiments, the uppermost surface 116u of the base portion 116 extends to a depth greater than the annular trench depth 704.

In FIG. 9A, the third cut 902 is shown where the inner edge of the second trim blade 114 is aligned with the outer sidewall of the annular trench 108. In FIG. 9B, the third cut 902 is shown where the inner edge of the second trim blade is substantially centered between sidewalls of the annular trench 108. Other alignments of the inner edge of the second trim blade have been contemplated and are within the scope of this disclosure. FIGS. 9A-9B illustrate cross-sectional views 900a-900b of some embodiments corresponding to act 212 of FIG. 2.

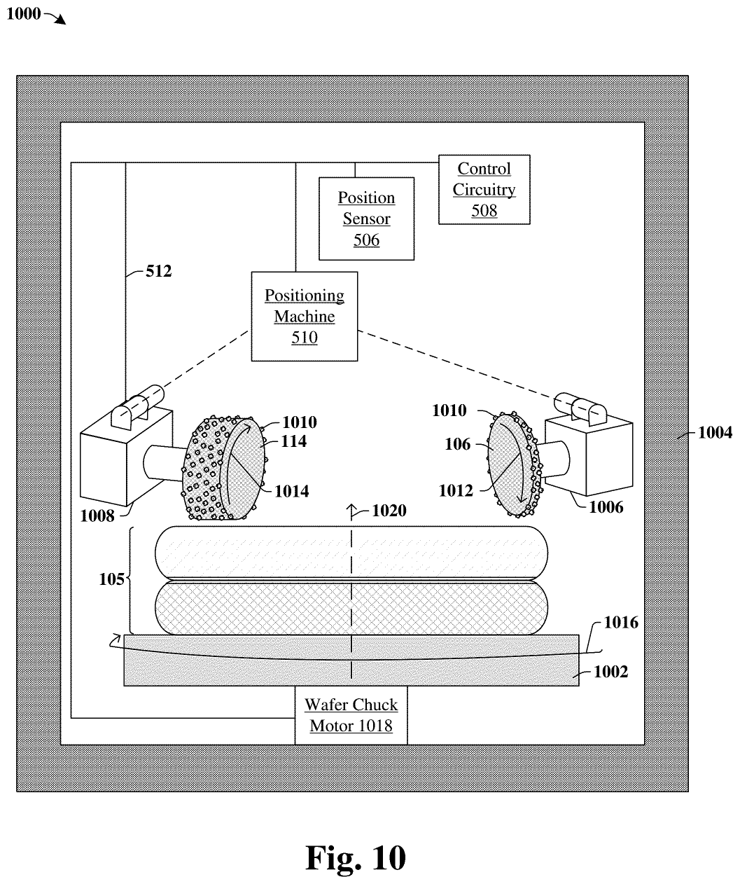

FIG. 10 illustrates a cross-sectional view of some embodiments of a dual blade trimming tool comprising a position sensor, a first trim blade configured to form an annular trench in the second wafer, and a second trim blade configured to remove a peripheral portion of a second wafer.

The cross-sectional view 1000 of FIG. 10 comprises a wafer chuck 1002, a position sensor 506, a second trim blade 114, a first trim blade 106, a positioning machine 510, and control circuitry 508. In some embodiments, the aforementioned apparatuses (e.g., 1002, 506, 114, 106, 510, 508) are arranged within a processing chamber defined by a housing 1004. In some other embodiments, each apparatus (e.g., 1002, 506, 114, 106, 510, 508) may be arranged in different housings (e.g., 1004). For example, in some other embodiments, the first trim blade 106 and the position sensor 506 is in a first housing (e.g., 1004); and the second trim blade 114 and an additional position sensor (not shown) is in a second housing (not shown).

In some embodiments, the first trim blade 114 is coupled to a first positioning arm 1006 and the second trim blade 114 is connected to a second positioning arm 1008. The first and second positioning arms 1006, 1008 are each mechanically coupled to the positioning machine 510. The positioning machine 510 controls various parameters (e.g., angular velocity, location of the narrow and second trim blades 106, 114, etc.) of the first and second positioning arms 1006, 1008 and the narrow and second trim blades 106, 114 based on sensor data 504 gathered from the position sensor 506 and instructions sent by the control circuitry 508 interpreting the sensor data 504. In some embodiments, the control circuitry 508 is coupled to the first and second positioning arms 1006, 1008 through a direct wired connection 512 or a wireless connection (not shown). In some embodiments, the positioning machine is configured to position the inner edge of the second trim blade 114 over a point substantially centered between sidewalls of the annular trench 108. Thus, the second trim blade 114 may remove the peripheral portion 112 of the second wafer 104 without directly contacting the central portion 110 of the second wafer 104 to eliminate peeling of the second wafer 104 caused by the second trim blade 114.

In some embodiments, the position sensor 506 is positioned directly above the wafer chuck 1002, the positioning machine 510 is positioned around a periphery of the wafer chuck 1002, the first trim blade 106 and the second trim blade 114 are laterally surrounding the wafer chuck 1002, on opposite side of the wafer chuck.

In some embodiments, the first trim blade 106 and the second trim blade 114 each comprise an abrasive surface 1010 such as, for example, a diamond grit. In some embodiments, the first trim blade 106 is configured to rotate 1012 as it forms an annular trench 108 between the central portion 110 and the peripheral portion 112 of the second wafer 104. In some embodiments, the second trim blade 114 is configured to rotate 1014 independent from the first trim blade 106 as it removes the peripheral portion 112 of the second wafer 104 defined by the annular trench 108. In some embodiments, the wafer chuck 1002 is configured to rotate 1016 as the first trim blade 106 or second trim blade 114 is “ON” and rotating 1012, 1014 to remove the peripheral portion 112 of the second wafer 104.

In some embodiments, the first trim blade 106 has a first blade width W1 (see FIG. 1A) between approximately 0.1 and 0.3 millimeters, between 0.05 and 0.2 millimeters, between 0.15 and 0.3 millimeters, or approximately within another suitable range. In some embodiments, the second trim blade 114 has a second blade width W2 (see FIG. 1B) between approximately 1.5 and 3 millimeters, between 1.7 and 2.4 millimeters, between 2.1 and 3 millimeters, or approximately within another suitable range. In some embodiments, the second blade width W2 is over 10 times the first blade width W1.

In some embodiments, the wafer chuck 1002 is arranged at a bottom of the housing 1004 within the processing chamber and is configured to hold a wafer such as, for example, the wafer stack 105.

In some embodiments, the wafer chuck 1002 is mechanically coupled to a wafer chuck motor 1018 by a mechanical linkage directly beneath the wafer chuck 1002. In further embodiments, the wafer chuck motor 1018 rotates 1016 the wafer chuck 1002 along a first axis 1020 based on instructions received from the control circuitry 508. In some embodiments, the narrow and second trim blades 106, 114 perform up-cuts on the second wafer, wherein the wafer chuck 1002 rotates 1016 in a first direction, and the rotation 1012, 1014 of the first trim blade 106 or second trim blade 114 opposes the rotation 1016 of the wafer chuck 1002 in the first direction. In other embodiments, the wafer chuck 1002 remains stationary as the first trim blade 106 and/or the second trim blade 114 rotates around the second wafer 104.

In some other embodiments, the first trim blade 106 is coupled to a different position sensor 506 than the second trim blade 114. In other embodiments, the first trim blade 106 and the second trim blade 114 are coupled to the same position sensor 506. In some embodiments, the position sensor 506 is configured to locate alignment marks on or within a first wafer 102 arranged within the housing 1004 to align the first trim blade 106 and/or the second trim blade 114 near an edge of the wafer stack 105. In other embodiments, the position of the wafer stack 105 as a whole is considered when aligning the first trim blade 106 and the second trim blade 114 near an edge of the wafer stack 105. In some embodiments, the position sensor 506 uses a camera to capture images at four sites evenly spaced around the wafer edge. These images are then interpreted by the control circuitry 508 to determine the alignment, center and radius of the wafer stack 105. In further embodiments, the four sites are at positions 90 degrees apart when measured from the center of the wafer stack 105, and the first positioning arm 1006 is disposed halfway between two adjacent sites of the four sites, and the second positioning arm 1008 is disposed on an opposite side of the stacked wafer, halfway between two other adjacent sites of the four sites.

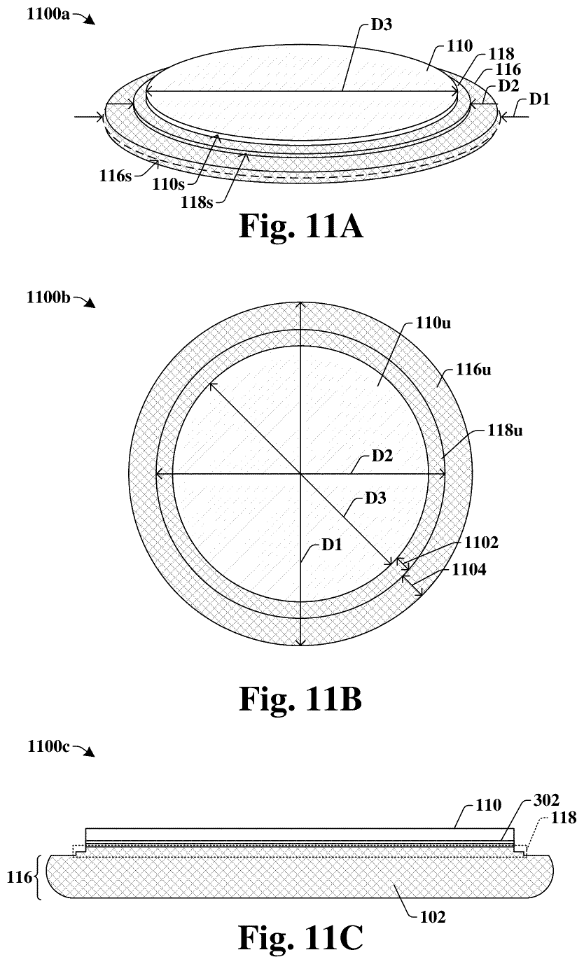

FIGS. 11A-11C illustrate various views of some embodiments of a second wafer arranged over and bonded to a first wafer, wherein a step structure extends from the first wafer. FIG. 11A illustrates a perspective view 1100a of some embodiments of a stack of wafers bonded to one another.

The perspective view 1100a of FIG. 11A shows the wafer stack 105 comprising the central portion 110 of the second wafer 104 arranged over and bonded to the first wafer 102. In some embodiments, a center of the second wafer 104 may directly overlie a center of the first wafer 102, such that the first and second wafers 102, 104 are aligned and concentric with one another. The step structure 118 of the first wafer 102 extends out of the first wafer 102 and is between a top of an outer sidewall 116s of the base portion 116 and a bottom of an outer sidewall 110s of the central portion 110. In some embodiments, the first and second wafers 102, 104 may be monocrystalline and each comprise a semiconductor material such as, for example, silicon, germanium, or the like.

In some embodiments, the base portion 116 has outer sidewalls 116s that are substantially curved or beveled, whereas the central portion 110 second wafer 104 and the step structure 118 have outer sidewalls 110s, 118s that are substantially vertical or straight. In such embodiments, the central portion 110 of the second wafer 104 may have substantially vertical or straight outer sidewalls 110s because the second wafer 104 was trimmed in the first trimming process after being bonded to the first wafer 102. Further, in some embodiments, the outer sidewalls 118s of the step structure are substantially vertical or straight due to the second trimming process.

The top view 1100b of FIG. 11B shows the wafer stack 105 of FIG. 11A. In some embodiments, the first wafer 102, the second wafer 104, and the step structure 118 have overall circular shapes. The first wafer 102 has a first diameter D₁, the step structure 116 has a second diameter D₂, and the second wafer 104 has a third diameter D₃. The second diameter D₂ of the step structure 118 is less than the first diameter D₁ of the first wafer 102. The third diameter D₃ of the second wafer 104 is less than the second diameter D₂ of the step structure 118.

The step structure 118 has an exposed upper surface 118u that forms a ring around the uppermost surface 110u of the central portion 110. The exposed upper surface 118u has a first annular ring width 1102. The uppermost surface 116u of the base portion 116 extending past the step structure 118 forms a second ring around the central portion 110 with a second annular ring width 1104 that is greater than the first annular ring width 1102. In some embodiments, the second annular ring width 1104 is more than 5 times greater than the first annular ring width 1102.

In some embodiments, the first annular ring width 1102 of the upper surface 118u of the step structure 118 is between approximately 50 micrometers and 300 micrometers, between 50 micrometers and 200 micrometers, between 100 micrometers and 200 micrometers, or approximately within another suitable range. In some embodiments, the second annular ring width 1104 of the uppermost surface 116u of the base portion 116 is between approximately 1.5 millimeters and 2.5 millimeters, between 0.5 millimeters and 2 millimeters, between 2 millimeters and 3 millimeters, or approximately within another suitable range.

FIG. 11C illustrates a cross-sectional view 1100c of some embodiments of the second wafer 104 arranged over and bonded to the first wafer 102. In some embodiments, the cross-sectional view 1100c of FIG. 11C corresponds to a cross-sectional view of the top view 1100b in FIG. 11B and/or the perspective view 1100a of FIG. 11A.

The base portion 116 of the first wafer 102 extends beneath the step structure 118. The step structure 118 extends between and separates the base portion 116 of the first wafer 102 and the second wafer 104.

In some embodiments, the first wafer 102 and the second wafer 104 are bonded together through the bonding layers 302. In some embodiments, the bonding layer 302 also has the third diameter D₃, whereas in other embodiments, the bonding layer 302 is wider than or narrower than the central portion 110.

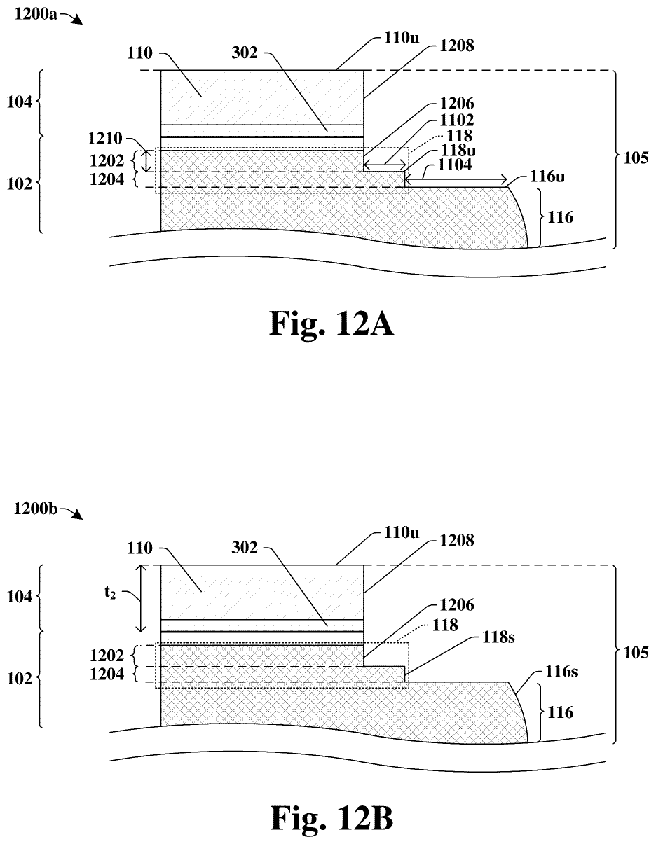

FIGS. 12A-12B illustrate cross-sectional views 1200a-1200b of the outer edge of the wafer stack 105. In some embodiments, as shown in FIG. 12A, the step structure 118 comprises an upper step portion 1202 and a lower step portion 1204. The upper step portion 1202 extends between the lower step portion 1204 and the central portion 110 of the second wafer 104. The upper step portion 1202 has the third diameter D₃ and has an outer sidewall 1206 aligned with an outer sidewall 1208 of the central portion 110 of the second wafer 104. The lower step portion 1204 has the second diameter D₂ and has the exposed upper surface 118u which extends outwards from the outer sidewall 1206 of the upper step portion 1202. The outer sidewall 1206 of the upper step portion 1202 has a first height 1210. The first height 1210 is approximately between 10 micrometers and 30 micrometers, between 5 micrometers and 20 micrometers, between 20 micrometers and 40 micrometers, or approximately within another suitable range.

FIG. 12B illustrates an additional cross-sectional view 1200b of the outer edge of the wafer stack 105. In some embodiments, the outer sidewall 1206 of the upper step portion 1202 and an outer sidewall 118s of the lower step portion 1204 are both substantially perpendicular to the exposed upper surface 118u. In further embodiments, an outer sidewall 116s of the base portion 116 is substantially rounded or beveled.

Accordingly, in some embodiments, the present disclosure relates to a method including: receiving a wafer stack comprising a first wafer and a second wafer, removing a top portion of the second wafer, aligning a first trim blade with a first blade width over the second wafer, using the first trim blade to form an annular trench that separates a central portion of the second wafer from a peripheral portion of the second wafer, wherein the annular trench is arranged at a first distance from an outer perimeter of the second wafer, and wherein the annular trench extends from a top surface of the second wafer to an annular trench depth beneath the top surface of the first wafer, aligning a second trim blade with a second blade width over the peripheral portion of the second wafer, wherein the second blade width is greater than the first blade width, and removing the peripheral portion of the second wafer using the second trim blade.

In other embodiments, the present disclosure relates to a dual trim blade tool. The dual trim blade tool contains a housing. A wafer chuck is positioned within the housing, and is configured to hold a wafer stack. Control circuitry is configured to control the wafer chuck. A first trim blade having a first blade width is positioned within the housing over the wafer chuck and is configured to cut an annular trench between a central portion and a peripheral portion of the wafer stack as directed by the control circuitry. A second trim blade having a second blade width is positioned within the housing over the wafer chuck and is configured to remove the peripheral portion of the wafer stack as directed by the control circuitry, the second width being greater than the third width.

In yet other embodiments, the present disclosure relates to a method including: receiving a first wafer, aligning a first trim blade with a first blade width over the first wafer, using the first trim blade to form an annular trench between a central portion of the first wafer and a peripheral portion of the first wafer, wherein the annular trench is arranged at a first distance from an outer perimeter of the first wafer, and wherein the annular trench extends from a top surface of the first wafer to an annular trench depth beneath the top surface of the first wafer, aligning a second trim blade with a second blade width over the peripheral portion of the first wafer, wherein the second blade width is greater than the first blade width, and removing the peripheral portion of the first wafer using the second trim blade.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving a wafer stack comprising a first wafer and a second wafer;
removing a top portion of the second wafer;
aligning a first trim blade having a first blade width over the second wafer;
using the first trim blade to form an annular trench that separates a central portion of the second wafer from a peripheral portion of the second wafer, wherein the annular trench is arranged at a first distance from an outer perimeter of the second wafer, and wherein the annular trench extends from a top surface of the second wafer to an annular trench depth beneath the top surface of the first wafer;
aligning a second trim blade having a second blade width over the peripheral portion of the second wafer, wherein the second blade width is greater than the first blade width; and
removing the peripheral portion of the second wafer using the second trim blade.

2. The method of claim 1, wherein during the removing of the peripheral portion of the second wafer, the second trim blade is separated from the central portion of the second wafer by a portion of the annular trench.

3. The method of claim 1, wherein the second trim blade overlies the annular trench while removing the peripheral portion of the second wafer, and removes portions of the first wafer to a first depth below the annular trench depth.

4. The method of claim 3, wherein an inner edge of the second trim blade overlies a point substantially centered between sidewalls of the annular trench while removing the peripheral portion of the second wafer.

5. The method of claim 1, wherein after the annular trench is formed, the peripheral portion of the wafer stack comprises a bonded portion where the second wafer is bonded to the first wafer, the bonded portion having a width less than 100 micrometers.

6. The method of claim 5, wherein the peripheral portion of the wafer stack comprises an unbonded portion where the first wafer is separated from the second wafer, and wherein the unbonded portion is spaced from the central portion of the second wafer by both the bonded portion and the annular trench.

7. The method of claim 1, wherein the wafer stack comprises a bonded area and an unbonded area peripheral to the bonded area, and wherein after the annular trench is formed, the annular trench has an inner sidewall facing the unbonded area within 300 micrometers of the unbonded area.

8. The method of claim 1, wherein removing the peripheral portion of the second wafer using the second trim blade delineates a step structure of the first wafer and a base portion of the first wafer beneath the step structure.

9. The method of claim 1, wherein the annular trench has a first annular width corresponding to the first blade width, and the peripheral portion has a second annular width that is less than or equal to the second blade width.

10. A dual trim blade tool, comprising:
a housing;
a wafer chuck positioned within the housing, configured to hold a wafer stack;
control circuitry configured to control the wafer chuck;
a first trim blade having a first blade width positioned within the housing over the wafer chuck and configured to cut an annular trench between a central portion and a peripheral portion of the wafer stack as directed by the control circuitry; and
a second trim blade having a second blade width positioned within the housing over the wafer chuck and configured to remove the peripheral portion of the wafer stack as directed by the control circuitry, the second blade width being greater than the first blade width.

11. The dual trim blade of claim 10, further comprising:
a position sensor positioned within the housing and directly above the wafer chuck, the position sensor configured to relay position data of the wafer stack to the control circuitry; and
a positioning machine positioned within the housing around a periphery of the wafer chuck and coupled to the first trim blade and the second trim blade, the positioning machine configured to reposition the first trim blade and the second trim blade as directed by the control circuitry based on the position data.

12. The dual trim blade tool of claim 11, wherein a first arm of the positioning machine is configured to control the position and angular velocity of the first trim blade under direction of the control circuitry and a second arm of the positioning machine is configured to control the position and angular velocity of the second trim blade under direction of the control circuitry.

13. The dual trim blade tool of claim 10, wherein the first trim blade and the second trim blade are positioned on opposite sides of the wafer chuck, and wherein the second blade width is over ten times greater than the first blade width.

14. The dual trim blade tool of claim 10, further comprising:
a wafer chuck motor positioned within the housing and coupled to the wafer chuck, the wafer chuck motor configured to rotate the wafer chuck along a first axis as directed by the control circuitry; and
a mechanical linkage directly beneath the wafer chuck, mechanically coupling the wafer chuck motor and the wafer chuck.

15. A method comprising:
receiving a first wafer;
aligning a first trim blade having a first blade width over the first wafer;
using the first trim blade to form an annular trench between a central portion of the first wafer and a peripheral portion of the first wafer, wherein the annular trench is arranged at a first distance from an outer perimeter of the first wafer, and wherein the annular trench extends from a top surface of the first wafer to a first annular trench depth beneath the top surface of the first wafer;
aligning a second trim blade having a second blade width over the peripheral portion of the first wafer, wherein the second blade width is greater than the first blade width; and
removing the peripheral portion of the first wafer using the second trim blade.

16. The method of claim 15, wherein the first wafer is bonded to a second wafer beneath the first wafer, and wherein the removal of the peripheral portion of the first wafer also removes portions of a peripheral portion of the second wafer.

17. The method of claim 16, further comprising:
after using the first trim blade to form the annular trench, using the first trim blade to extend the annular trench to a second annular trench depth beneath the top surface of the second wafer.

18. The method of claim 17, wherein the annular trench has a first annular width corresponding to the first blade width, and the peripheral portion has a second annular width that is less than or equal to the second blade width.

19. The method of claim 17, wherein the first annular trench depth is substantially half of the second annular trench depth.

20. The method of claim 15, wherein the first annular trench depth is greater than half of a thickness of the first wafer.
